(19) United States
(12) Patent Application Publication
(10) Pub. No.: US 2014/0227458 A1
(43) Pub. Date: Aug. 14, 2014

(54) PLASMA EVALUATION METHOD, PLASMA PROCESSING METHOD AND PLASMA PROCESSING APPARATUS

(71) Applicants: Takayuki Karakawa, Miyagi (JP); Hirokazu Ueda, Miyagi (JP)

(72) Inventors: Takayuki Karakawa, Miyagi (JP); Hirokazu Ueda, Miyagi (JP)

(73) Assignee: TOKYO ELECTRON LIMITED, Tokyo (JP)

(21) Appl. No.: 14/112,172

(22) PCT Filed: Apr. 18, 2012
(86) PCT No.: PCT/JP2012/060474

§ 371 Date: Oct. 16, 2013

(30) Foreign Application Priority Data
Apr. 18, 2011 (JP) 2011-092280

(51) Int. Cl. G01J 3/443; C23C 16/50; C23C 16/52

(52) U.S. Cl. CPC G01J 3/443; C23C 16/52; C23C 16/50; G01J 2003/4435
USPC 427/569; 356/316; 118/712

(57) ABSTRACT

Disclosed is a plasma evaluation method that evaluates plasma P that forms a nitride film by an atomic layer deposition method. First, light emission from the plasma P generated from a gas G that contains nitrogen atoms and hydrogen atoms is detected. Then, evaluation of the plasma P is performed by using a result of comparing an intensity ratio between a first peak caused by hydrogen atoms and a second peak different from the first peak and caused by hydrogen atoms in an intensity spectrum of the detected light emission with a reference value calculated in advance from a relationship between the intensity ratio and an indicator that indicates a film quality of the nitride film.

### TECHNICAL FIELD

The present disclosure relates to a plasma evaluation method, a plasma processing method, and a plasma processing apparatus.

### BACKGROUND

There is known a method of detecting light emission from plasma, and setting the a power to be supplied to an electrode so as to maximize the emitted light intensity of NH radicals detected at a wavelength of 324.01 nm when forming a nitride film by a plasma CVD method. See, e.g., Japanese Patent Laid-open Publication H3-243772.

### PRIOR ART DOCUMENT

### Patent Document

Patent Document 1: Japanese Patent Laid-open Publication No. H3-243772

### DISCLOSURE OF THE INVENTION

### Problems to be Solved

As for a method of forming a nitride film, for example, an atomic layer deposition (“ALD”) method may be used. In the ALD method, the following steps (1) to (4) are repeated to form a nitride film on a substrate.

(1) adsorbing a film forming material on the substrate within a processing chamber.

(2) removing an excessively adsorbed film forming material by a purge gas.

(3) performing a plasma nitriding processing on the film forming material by using plasma generated from a gas that contains nitrogen atoms.

(4) removing the gas that remains within the processing chamber by a purge gas.

Formation of a nitride film by the ALD method requires a longer time than that by a plasma CVD method. This is because, especially, the purge processes (2) and (4) require a long time.

In order to form a nitride film of a good film quality (a highly dense nitride film) by the ALD method, it is required to optimize a plasma condition. For this purpose, it is required to form nitride films under different plasma conditions, and then to precisely evaluate the film qualities of the nitride films obtained thereby. In order to more precisely evaluate a film quality, it is required to form the nitride films to be evaluated in a film thickness of at least 10 nm. However, it is not efficient to form the nitride films having the film thickness of 10 nm or more using the ALD method, since the ALD method requires a very long time (e.g., 1 to 2 hours) as compared to the plasma CVD method. Also, it is known that the film quality of nitride films formed under the different plasma conditions, for example, the denseness of the films may be evaluated by measuring wet etching rates in, for example, a 0.5% hydrofluoric acid aqueous solution. However, the operation of measuring the wet etching rates in the hydrofluoric acid aqueous solution is troublesome, and requires a considerable operation time. Thus, there is a problem in terms of evaluation efficiency in that a long time is required for the film quality evaluation of the nitride films as well as the formation of the nitride films.

The present disclosure has been made in consideration of the problems as described above, and an object of the present disclosure is to provide a plasma evaluation method capable of determining, in a short time, a plasma condition for forming a nitride film of a good film quality, a plasma processing method and a plasma processing apparatus.

### Means to Solve the Problems

In order to solve the above problems, according to an aspect, the present disclosure provides a method of evaluating plasma, in particular a method of evaluating plasma for forming a nitride film by an atomic layer deposition method. The plasma evaluation method includes: detecting light emission from the plasma generated from a gas that contains nitrogen atoms and hydrogen atoms; and performing evaluation of the plasma by using a result of comparing an intensity ratio between a first peak caused by hydrogen atoms and a second peak different from the first peak and caused by hydrogen atoms in an intensity spectrum of the detected light emission with a reference value calculated in advance from a relationship between the intensity ratio and an indicator that indicates a film quality of the nitride film.

The present inventors have found that in an atomic layer deposition method, the intensity ratio of two peaks caused by hydrogen atoms in an intensity spectrum of light emission from plasma is closely related to a film quality of a nitride film formed by the plasma. The plasma evaluation method as described above may evaluate whether or not plasma for forming a nitride film of a good film quality has been generated based on the intensity ratio of two peaks caused by hydrogen atoms. Thus, it is not required to actually form nitride films under different plasma conditions, nor evaluate the nitride films. Accordingly, a plasma condition for forming a nitride film of a good film quality may be determined within a short time (e.g., within 10 minutes).

The first peak may have a peak wavelength of 656.2 nm, and the second peak may have a peak wavelength of 486.1 nm.

The plasma evaluation method may further include, when the intensity ratio is less than the reference value, changing a condition of the plasma so that the intensity ratio becomes equal to or larger than the reference value, after the evaluation of the plasma. Accordingly, the plasma condition may be changed into a plasma condition for forming a nitride film of a good film quality.

After the changing of the condition of the plasma, the method may return back to the detecting of the light emission from the plasma. Accordingly, a control may be made so as to maintain the plasma condition for forming a nitride film of a good film quality.

The plasma may be generated by microwave. When the microwave is used as a plasma source, plasma that has a lower electron temperature and a higher electron density may be obtained as compared with that obtained using other plasma sources generated by, for example, capacitive coupling or inductive coupling. Thus, the plasma nitriding processing rate may be improved while decreasing damage in forming a nitride film. Also, when the microwave is used as the plasma source, a wider processing pressure range of the plasma nitriding processing may be taken as compared to when other plasma sources are used.

The plasma may be generated by a radial line slot antenna. When the radial line slot antenna is used, the microwave may be uniformly introduced into the processing chamber, generating the plasma uniformly.

According to another aspect, the present disclosure provides a plasma processing method including: performing a plasma processing on a layer adsorbed on a substrate by using the plasma evaluated by the plasma evaluation method as described above. Accordingly, a nitride film of a good film quality may be formed on the substrate.

According to a still another aspect, the present disclosure provides a plasma processing apparatus that forms a nitride film by an atomic layer deposition method. The plasma processing apparatus includes: a processing chamber; a gas supply source configured to supply a gas that contains nitrogen atoms and hydrogen atoms into the processing chamber; a plasma generator configured to generate plasma from the gas within the processing chamber; a light detector configured to detect light emission from the plasma; and a control unit that performs evaluation of the plasma by using a result of comparing an intensity ratio between a first peak caused by hydrogen atoms and a second peak different from the first peak and caused by the hydrogen atoms in an intensity spectrum of the detected light emission with a reference value calculated in advance from a relationship between the intensity ratio and an indicator that indicates a film quality of the nitride film.

In the plasma processing apparatus, the plasma evaluation method as described above may be performed. Accordingly, a plasma condition for forming a nitride film of a good film quality may be determined in a short time.

### Effect of the Invention

The present disclosure provides a plasma evaluation method capable of determining, in a short time, a plasma condition for forming a nitride film of a good film quality, a plasma processing method, and a plasma processing apparatus.

### BRIEF DESCRIPTION OF THE DRAWINGS

FIG. 1 is a cross-sectional view schematically illustrating a plasma processing apparatus according to an exemplary embodiment.

FIG. 2 is a cross-sectional view schematically illustrating the plasma processing apparatus according to the exemplary embodiment.

FIG. 3 is a view illustrating a slot plate of the plasma processing apparatus according to the exemplary embodiment, when viewed in the Z direction.

FIG. 4 is a flow chart illustrating respective steps of a plasma evaluation method according to an exemplary embodiment.

FIG. 5 is a graph illustrating an example of spectra of light emission intensity from plasma.

FIG. 6 is a graph illustrating a portion of the spectra illustrated in FIG. 5.

FIG. 7 is a graph illustrating a portion of the spectra illustrated in FIG. 5.

FIG. 8 is a graph illustrating a portion of the spectra illustrated in FIG. 5.

FIG. 9 is a graph illustrating an example of a relationship between an intensity ratio of two peaks caused by hydrogen atoms, and a wet etching rate of a silicon nitride film in 0.5% hydrofluoric acid aqueous solution.

FIG. 10 is a graph illustrating an example of a relationship between an intensity of one peak caused by hydrogen atoms and a wet etching rate of a silicon nitride film in 0.5% hydrofluoric acid aqueous solution.

FIG. 11 is a cross-sectional view schematically illustrating a plasma processing apparatus according to another exemplary embodiment.

FIG. 12 is a timing chart schematically illustrating a plasma processing method according to an exemplary embodiment.

FIG. 13 is a table representing an example of a gas flow rate when a silicon nitride film is formed.

### DETAILED DESCRIPTION TO EXECUTE THE INVENTION

Hereinafter, an exemplary embodiment of the present disclosure will be specifically described with reference to the accompanying drawings. Also, in the description of drawings, the same numerals are used for the same or equivalent elements, and redundant description thereof will be omitted.

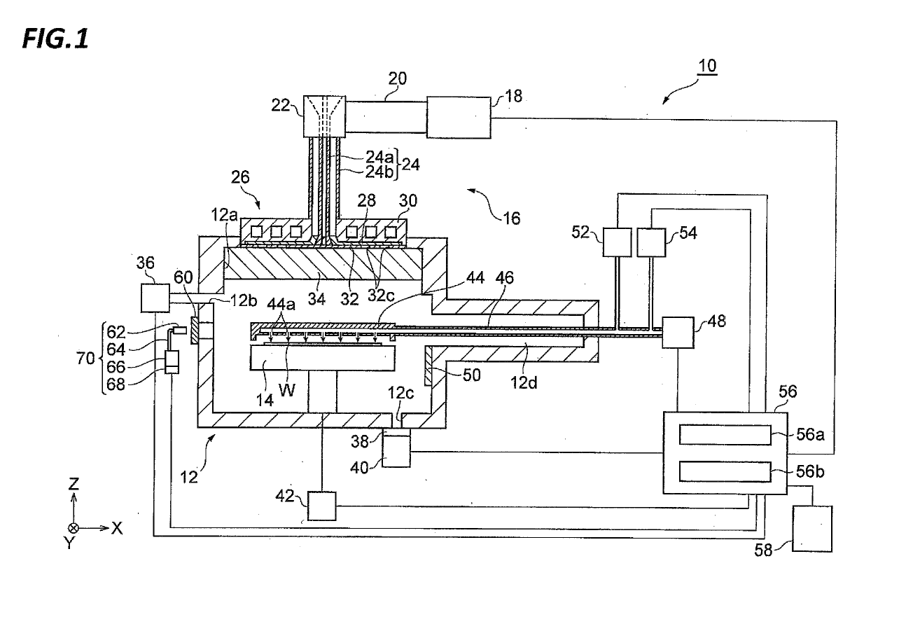

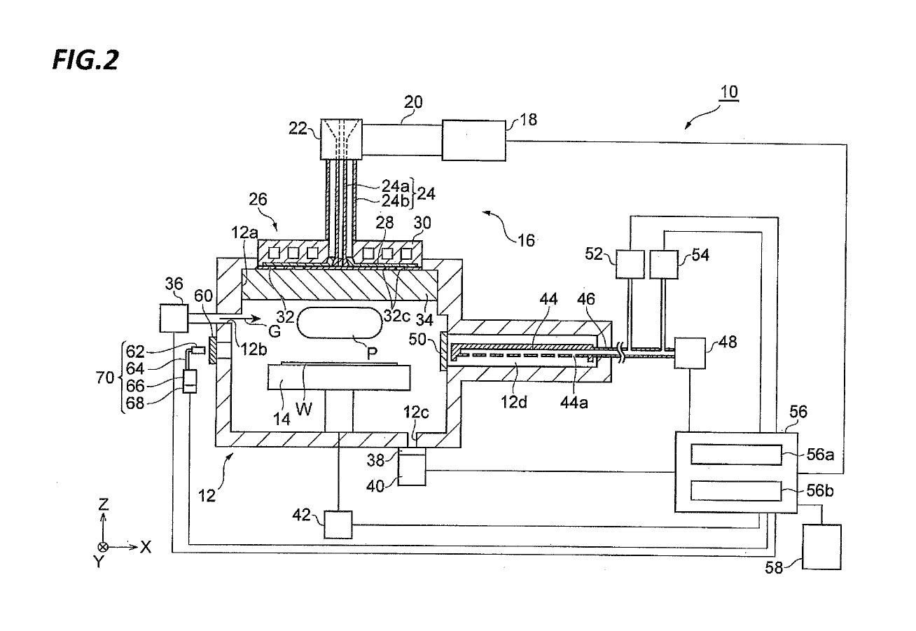

FIGS. 1 and 2 are cross-sectional views schematically illustrating a plasma processing apparatus according to an exemplary embodiment. In FIG. 2, a head unit 44 in FIG. 1 is accommodated. In FIGS. 1 and 2, an XYZ rectangular coordinate system is illustrated. The plasma processing apparatus 10 illustrated in FIGS. 1 and 2 is an atomic layer deposition apparatus (ALD apparatus). The plasma processing apparatus 10 is provided with a processing chamber 12, a gas supply source 36 configured to supply a gas G into a processing chamber 12, and a plasma generator 16 configured to generate plasma P within the processing chamber 12. The plasma P is generated from the gas G. The gas G contains nitrogen atoms and hydrogen atoms. The gas G includes, for example, ammonia gas. The gas G may contain an inert gas such as, for example, Ar gas, or nitrogen gas.

The plasma processing apparatus 10 may be provided with a substrate holder 14 that holds a substrate W within the processing chamber 12. The substrate W is a semiconductor substrate such as, for example, a silicon substrate, and has a surface that is substantially parallel to an XY plane. The plasma P forms a nitride film such as, for example, a silicon nitride film, on the substrate W.

The plasma generator 16 is provided with a microwave generator 18 configured to generate microwave for plasma excitation, and a radial line slot antenna (RLSA: registered trademark) 26 configured to introduce the microwave into the processing chamber 12. The microwave generator 18 is connected to a mode converter 22 configured to convert a mode of the microwave, through a waveguide 20. The mode converter 22 is connected to the radial line slot antenna 26 through a coaxial waveguide 24 that includes an inner waveguide 24a and an outer waveguide 24b. Accordingly, the mode of the microwave generated by the microwave generator 18 is converted by the mode converter 22 before the microwave reaches the radial line slot antenna 26. The frequency of the microwave generated by the microwave generator 18 is, for example, 2.45 GHz.

The radial line slot antenna 26 is provided with a dielectric window 34 that blocks an opening 12a formed in the processing chamber 12, a slot plate 32 provided outside of the dielectric window 34, a cooling jacket 30 provided outside of the slot plate 32, and a dielectric plate 28 disposed between the slot plate 32 and the cooling jacket 30. The dielectric window 34 is disposed to face the substrate W. The dielectric window 34 is made of, for example, a ceramic material such as, for example, aluminum oxide (Al₂O₃). The inner waveguide 24a is connected to the center of the slot plate 32, and the outer waveguide 24b is connected to the cooling jacket 30. The cooling jacket 30 also serves as a waveguide. Accordingly, the microwave is propagated between the inner waveguide 24a and the outer waveguide 24b, propagated to the dielectric plate 28 between the slot plate 32 and the cooling jacket 30, and transmitted through the dielectric window 34 from slots 32c to reach the inside of the processing chamber 12.

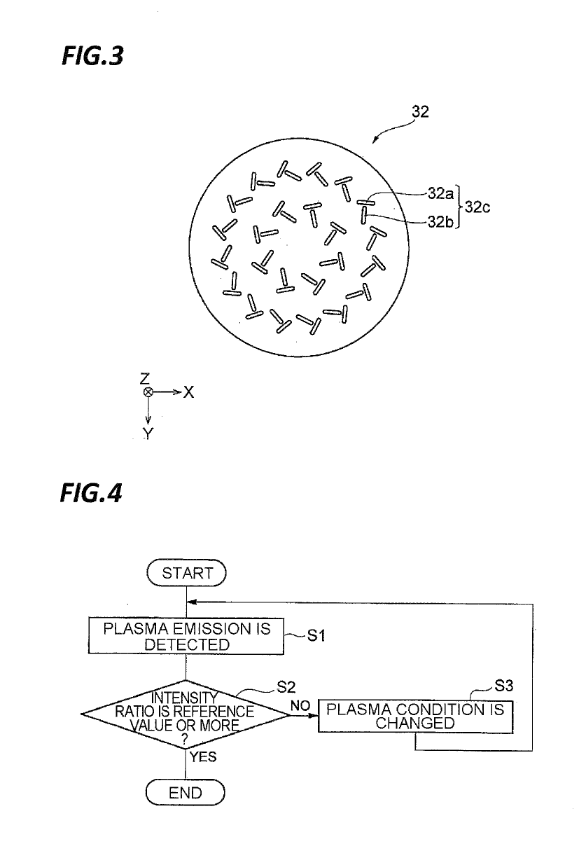

FIG. 3 is a view illustrating the slot plate 32 of the plasma processing apparatus 10, when viewed in the Z direction. In FIG. 3, an XYZ rectangular coordinate system is illustrated. The slot plate 32 is formed in, for example, a disk shape. A plurality of pairs of slots 32c are formed in a concentric shape on the slot plate 32, in which a pair of the slots include a slot 32a that extends in a first direction and a slot 32b that extends in a second direction perpendicular to the first 1 direction.

For example, referring to one slot 32c, the first direction is perpendicular to the second direction. One pair of slots 32c are disposed in the radial direction with respect to the center of the slot plate 32 to be spaced apart from each other at a predetermined interval, and are disposed in the circumferential direction of the slot plate 32 to be apart from each other at a predetermined interval. The microwave that is transmitted through the dielectric window 34 is introduced into the processing chamber 12 through one pair of slots 32c. The wavelength of the microwave is shortened when the microwave is transmitted through inside of the dielectric plate 28 (slow wave plate). Thus, the microwave may be introduced into the processing chamber 12 more efficiently as compared to the slots 32c.

Referring back to FIGS. 1 and 2, a plasma processing gas supply hole 12b is formed in a side wall of the processing chamber 12. The gas supply hole 12b may be formed in the dielectric window 34, and may be formed in a gas supply means that extends into the processing chamber 12. A gas supply source 36 is connected to the gas supply hole 12b. When the microwave is irradiated to the gas G supplied into the processing chamber 12, plasma P is generated at the dielectric window 34 side within the processing chamber 12. The generated plasma P is diffused toward the substrate W. An exhausting hole 12c configured to exhaust the gas within the processing chamber 12 is formed at the bottom of the processing chamber 12. A vacuum pump 40 is connected to the exhausting hole 12c via an auto pressure control (APC) valve 38. A temperature controller 42 configured to control the temperature of the substrate holder 14 is connected to the substrate holder 14. The temperature of the substrate holder 14 may be controlled to be in a range of, for example, preferably, 200° C. to 500° C., and more preferably, 300° C. to 400° C.

The plasma processing apparatus 10 is provided with a head unit 44 formed with gas supply holes 44a that are configured to supply a atomic layer deposition raw material gas (precursor) and a purge gas on the substrate W. The head unit 44 is connected to a driving device 48 by a support unit 46 that supports the head unit 44. The driving device 48 is disposed outside of the processing chamber 12. The head unit 44 and the support unit 46 are capable of moving in the X direction by the driving device 48. An accommodation unit 12d configured to accommodate the head unit 44 is provided in the processing chamber 12. As illustrated in FIG. 2, when the head unit 44 is accommodated in the accommodation unit 12d, a shutter 50 moves in the Z direction, thereby isolating the accommodation unit 12d. Also, the plasma processing apparatus 10 illustrated in FIGS. 1 and 2 are the same except that the head unit 44 is accommodated or not in the accommodation unit 12d.

An atomic layer deposition raw material gas supply source 52 and a purge gas supply source 54 are connected to and communicated with the hollow support unit 46. The raw material gas and the purge gas are supplied on the substrate W by the head unit 44 through the support unit 46 from the raw material gas supply source 52 and the purge gas supply source 54, respectively.

The plasma processing apparatus 10 is provided with a light detector 70 that detects light emitted from the plasma P. The light detector 70 is provided with a condensing lens 62 that is disposed to face a window 60 provided at a side wall of the processing chamber 12. Light emitted from the plasma P is incident on the condensing lens 62 through the window 60. A spectrometer 66 is connected to the condensing lens 62 through an optical fiber 64. The light is split into a spectrum by the spectrometer 66 and introduced into a photomultiplier 68. The light detector 70 is, for example, an optical emission spectroscopy (OES). The light detector 70 may be disposed at any position as long as light emission from the plasma P may be detected at the position.

The plasma processing apparatus 10 is provided with a control unit 56 configured to control the entire apparatus. The control unit 56 is connected to each of the microwave generator 18, the vacuum pump 40, the temperature controller 42, the driving device 48, the plasma processing gas supply source 36, the atomic layer deposition raw material gas supply source 52, the purge gas supply source 54, and the light detector 70. Accordingly, the control unit 56 may control each of the output of the microwave, the pressure within the processing chamber 12, the temperature of the substrate holder 14, the X-direction movement of the head unit 44, and the gas flow rate and the gas flowing time of each of the plasma processing gas, the atomic layer deposition raw material gas and the purge gas. The control unit 56 is, for example, a computer, and is provided with a computing device 56a such as, for example, a CPU, and a storage device 56b such as, for example, a memory or a hard disk. The storage device 56b may be a computer-readable recording medium. The recording medium is, for example, a CD, a NAND, a BD, a HDD, or a USB. Data from the light detector 70 are recorded in the storage device 56b. A display device 58 that displays various data to be controlled may be connected to the control unit 56.

As described below, the control unit 56 performs evaluation of plasma P by using a result of comparing an intensity ratio between a first peak caused by hydrogen atoms and a second peak different from the first peak and caused by hydrogen atoms in the intensity spectrum of detected light emission from plasma with a reference value calculated in advance from a relationship between the intensity ratio and an indicator that indicates a film quality of a nitride film. A program that allows the computer to execute the following plasma evaluation sequence is recorded in the storage device 56b.

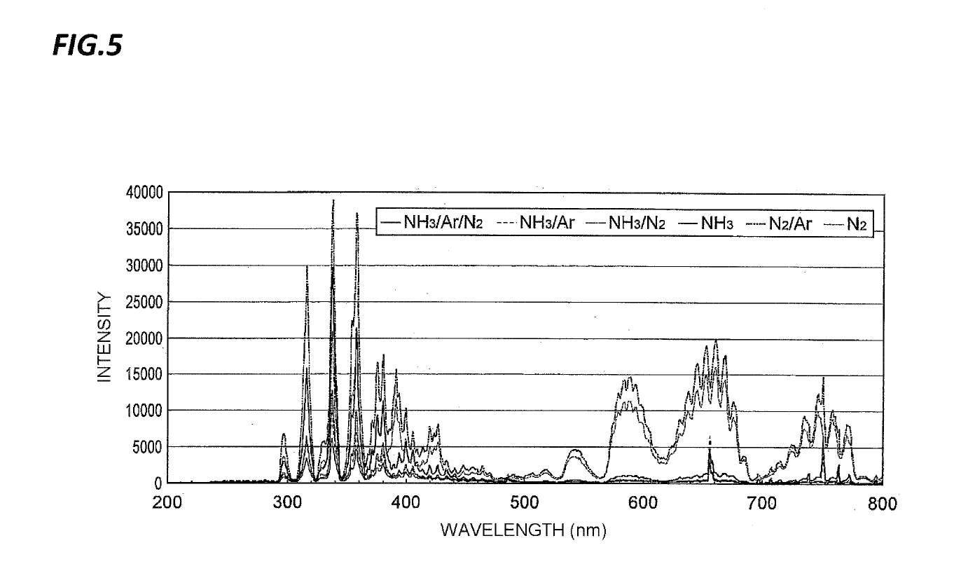

FIG. 4 is a flow chart illustrating respective steps of a plasma evaluation method according to an exemplary embodiment. In the plasma evaluation method according to the present exemplary embodiment, the plasma P that forms a nitride film through an atomic layer deposition method is evaluated. The plasma evaluation method according to the present exemplary embodiment may be performed by using the above described plasma processing apparatus 10, and may be performed as described below, for example, in the absence of the substrate W in FIG. 2.

(Step of Detecting Light Emission from Plasma)

First, light emission from the plasma P generated from the gas G is detected by the light detector 70 as illustrated in FIG. 2 (step S1). The intensity spectrum data of light emission from plasma obtained by the light detector 70 are recorded in the storage device 56b.

(Step of Evaluating Plasma)

After step S1, by the control unit 56, an intensity ratio between a first peak caused by hydrogen atoms and a second peak different from the first peak and caused by hydrogen atoms in an intensity spectrum of detected light emission from plasma is calculated. Meanwhile, a reference value that corresponds to a threshold level of determining whether a film quality of a nitride film is good or not is calculated in advance from a relationship between the intensity ratio and an indicator that indicates the film quality of the nitride film (e.g., a wet etching rate of the nitride film in 0.5% hydrofluoric acid aqueous solution). Then, by the control unit 56, evaluation on the plasma P is performed by using the result of comparing the intensity ratio with the reference value (step S2). In step S2, for example, it is determined whether the intensity ratio is equal to or larger than the reference value.

Here, the first peak has a peak wavelength of, for example, 656.2 nm, and the second peak has a peak wavelength of, for example, 486.1 nm. Assuming that the peak intensity of the first peak is I₆₅₆ and the peak intensity of the second peak is I₄₈₆, the intensity ratio is represented by, for example, I₆₅₆/I₄₈₆. When the intensity ratio I₆₅₆/I₄₈₆ is equal to or larger than the reference value (e.g., 4.5), it indicates that the plasma condition of the plasma P is a plasma condition that allows a nitride film of a good film quality to be formed. When the intensity ratio I₆₅₆/I₄₈₆ is smaller than the reference value, it indicates that the plasma condition of the plasma P is not a plasma condition that allows a nitride film of a good film quality to be formed. When the plasma condition is not a plasma condition that allows a nitride film of a good film quality to be formed, for example, an alarm may be displayed on the display device 58. In this manner, the plasma P may be evaluated. This plasma evaluation is effective when a nitride film is deposited by using a light detector that is incorporated in the plasma processing apparatus.

### (Step of Changing Plasma Condition)

After step S2, when the intensity ratio I₆₅₆/I₄₈₆ is smaller than the reference value, plasma conditions of plasma P may be changed such that the intensity ratio I₆₅₆/I₄₈₆ may become equal to or larger than the reference value (step S3). Accordingly, the plasma conditions may be changed into a plasma condition that allows a nitride film of a good film quality to be formed. The changeable plasma conditions of the plasma P may include, for example, a microwave output to be supplied to the microwave generator 18, the pressure within the processing chamber 12, the temperature of the substrate holder 14, the gas species of the gas G, the gas flow rate, and the flow rate ratio and flowing time of gases, and the place to which the gas G is supplied. Among them, the conditions that highly affect the state of the plasma P are the output of the microwave to be supplied to the microwave generator 18 and the pressure within the processing chamber 12.

After step S3, the process may return to step S1. Accordingly, a feedback control may be made so as to maintain the plasma conditions that allow the nitride film of the good film quality to be formed.

In the plasma evaluation method of the present exemplary embodiment, whether or not the plasma P capable of forming the nitride film of the good film quality has been generated may be evaluated based on the intensity ratio of two peaks caused by hydrogen atoms. Thus, it is not required to form nitride films under different plasma conditions or evaluate the nitride films. Accordingly, the plasma conditions that allow a dense nitride film of a good film quality to be formed may be determined within a short time (e.g., within 10 minutes). As a result, throughput in a nitride film forming process is improved.

Also, in the plasma evaluation method of the present exemplary embodiment, the change with time in state of the plasma P may be monitored. Accordingly the timing for replacement of constituent components of the plasma processing apparatus 10 may be determined. The plasma evaluation method is effective in determining the timing for replacement of the dielectric window 34 which is especially easily deteriorated among the constituent components of the plasma processing apparatus 10.

Also, the plasma evaluation method according to the present exemplary embodiment may be performed in the presence of the substrate W as illustrated in FIG. 2. In this case, while a nitride film is being formed on the substrate W by an atomic layer deposition method, the state of the plasma P may be monitored in real time. Accordingly, a nitride film of a good film quality may be stably formed. Also, when the plasma P generated by the microwave is used, the electron temperature of the plasma P is low (1.5 eV or less). Thus, the plasma nitriding processing rate may be improved while reducing damage when forming a nitride film. When a radial line slot antenna 26 is used, the microwave may be uniformly introduced into the processing chamber 12, and as a result, wide and uniform plasma P may be generated.

Hereinafter, a relationship between an intensity ratio of two peaks caused by hydrogen atoms and a film quality of a nitride film will be described by way of examples.

FIG. 5 is a graph illustrating an example of spectra of light emission intensity from plasma. The vertical axis represents light emission intensity, and the horizontal axis represents a wavelength (nm). FIG. 5 illustrates spectra at 200 nm to 800 nm in cases where following gases 1 to 6 were used, respectively, as the gas G for generating the plasma P.

gas 1: a mixed gas of NH₃, Ar and N₂

gas 2: a mixed gas of NH₃ and Ar

gas 3: a mixed gas of NH₃ and N₂

gas 4: NH₃

gas 5: a mixed gas of N₂ and Ar

gas 6: N₂

Also, plasma nitriding processes were performed on a silicon-containing compound adsorbed on a substrate W after setting the pressure within the processing chamber 12 in the process of performing the plasma processing to 5 Torr (666.5 Pa). In gases 1 to 4 that contain NH₃, a silicon nitride film may be formed (the silicon-containing compound is easily subjected to the plasma nitriding processing) while in gases 5 and 6 that do not contain NH₃, a silicon nitride film is hardly formed (the silicon-containing compound is hardly subjected to the plasma nitriding processing).

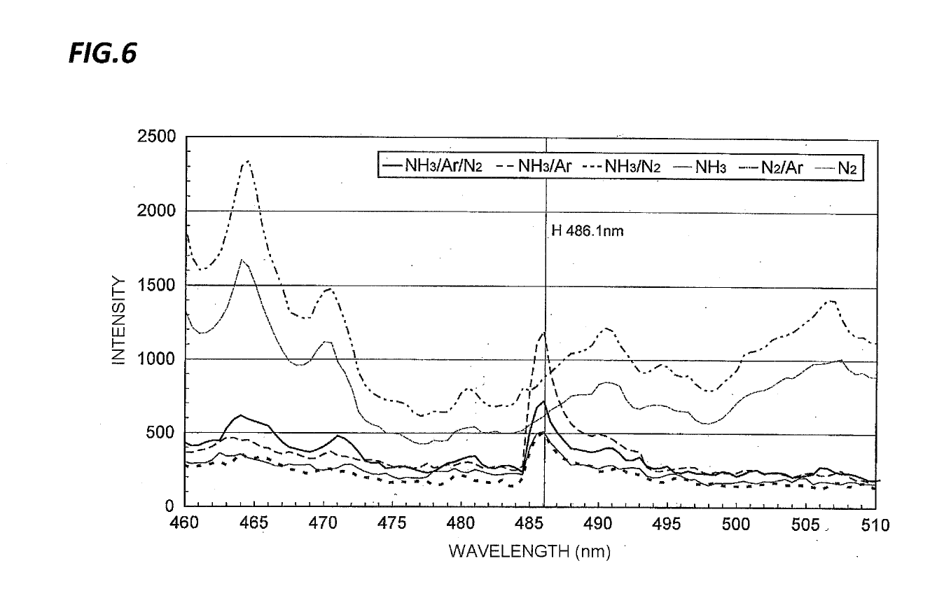

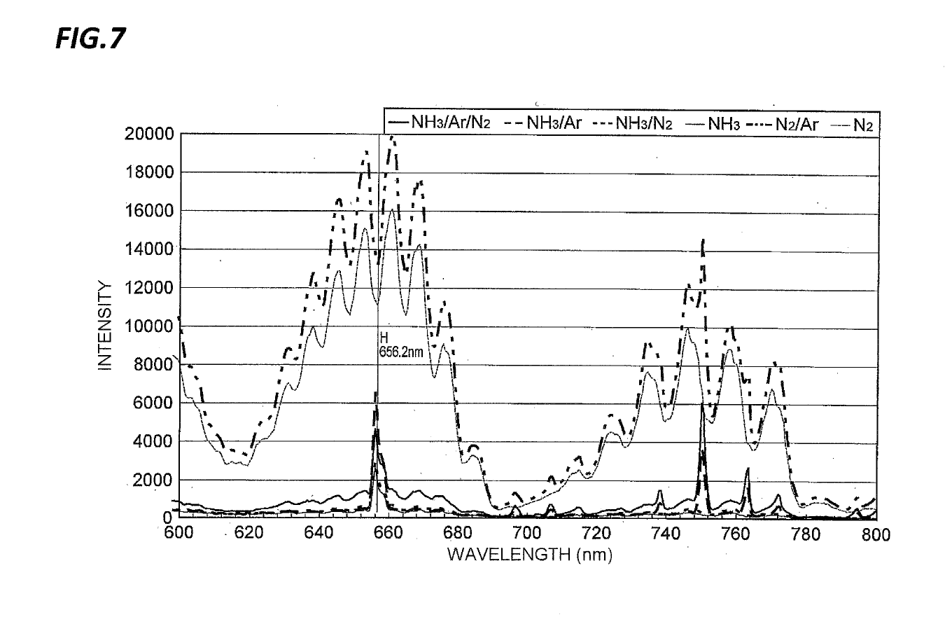

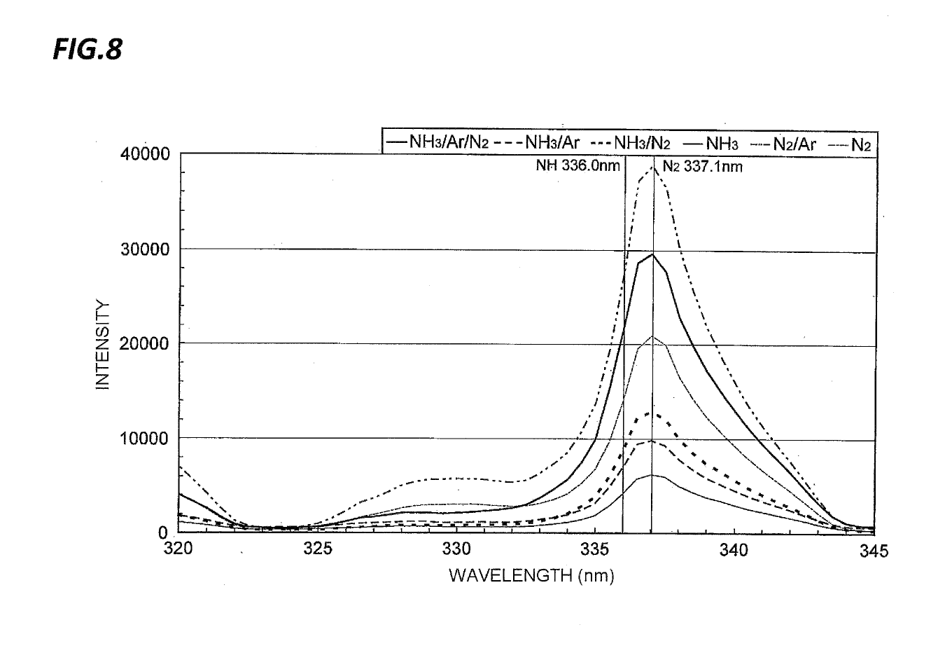

FIGS. 6 to 8 are graphs illustrating several portions of the spectra illustrated in FIG. 5 in a large scale. In the graph of FIG. 6, spectra at 460 nm to 510 nm are illustrated. In the graph of FIG. 7, spectra at 600 nm to 800 nm are illustrated. In the graph of FIG. 8, spectra at 320 nm to 345 nm are illustrated.

As illustrated in FIG. 6, peaks caused by hydrogen atoms at a peak wavelength of 486.1 nm were detected in gases 1 to 4. Also, as illustrated in FIG. 7, the peaks caused by hydrogen atoms at a peak wavelength of 656.2 nm were detected in gases 1 to 4. These peaks are caused by hydrogen atoms that are generated by dissociating NH₃. As illustrated in FIG. 8, the peaks caused by N₂ at a peak wavelength of 337.1 nm were detected, while no peaks caused by NH at a peak wavelength of 336.0 nm were detected. Since no peaks caused by NH were detected, it is estimated that NH₃ was dissociated into H and NH₂ radicals.

That is, in order to generate hydrogen atoms by efficiently dissociating NH₃, it is effective to mix N₂ or Ar to NH₃. In this case, it is believed that since high-speed electrons are generated when N₂ or Ar is excited in plasma, the electrons may easily dissociate NH₃ to generate hydrogen atoms efficiently.

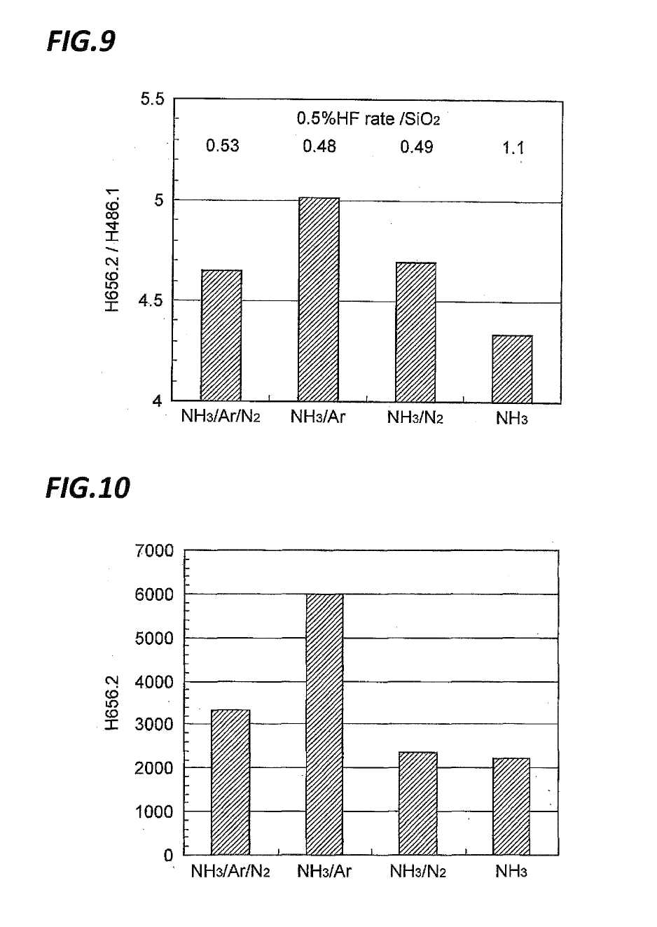

FIG. 9 is a graph illustrating an example of a relationship between an intensity ratio of two peaks caused by hydrogen atoms, and a wet etching rate of a silicon nitride film in 0.5% hydrofluoric acid aqueous solution. The vertical axis represents an intensity ratio ([a peak intensity caused by hydrogen atoms at a peak wavelength of 656.2 nm]/[a peak intensity caused by hydrogen atoms at a peak wavelength of 486.1 nm]). The horizontal axis represents the kinds of the gases G for generating the plasma P. FIG. 9 represents a wet etching rate when a formed silicon nitride film was subjected to a wet etching by 0.5% hydrofluoric acid aqueous solution. The values are relative values when it is assumed that a wet etching rate of a thermal oxide film obtained through thermal oxidation of silicon by using a WVG (wet vapor generator) at 950° C. is 1. A high-quality and dense silicon nitride film has a wet etching rate value which is 1 or less. As illustrated in FIG. 9, gas 1 forms a silicon nitride film having a wet etching rate of 0.53 and an intensity ratio of 4.65. Gas 2 forms a silicon nitride film having a wet etching rate of 0.48 and an intensity ratio of 5.02. Gas 3 forms a silicon nitride film having a wet etching rate of 0.49 and an intensity ratio of 4.70. Gas 4 forms a silicon nitride film having a wet etching rate of 1.1 and an intensity ratio of 4.33. From the graph of FIG. 9, it can be seen that the higher the intensity ratio is, the lower the wet etching rate of a silicon nitride film is (with the improvement of film quality, a silicon nitride film gets dense). That is, when the intensity ratio increases, the wet etching rate of a silicon nitride film monotonically decreases. It is believed that the higher the intensity ratio is, the more NH₂ radicals are generated. It is believed that as the nitriding process is carried out by the NH₂ radicals, the film quality of the silicon nitride films is improved.

In this case, the flow rate ratio of NH₃ gas to a plasma gas (Ar+N₂) is 0.15 in gas 1, 0.5 in gas 2, 0.5 in gas 3, and 1 in gas 4. The flow rate ratio is preferably less than 1, more preferably 0.8 or less, and is most preferably 0.05 to 0.5.

Also, from the result of FT-IR analysis, it can be seen that a silicon nitride film formed by an atomic layer deposition method includes more bindings of Si—NH groups as compared to a silicon nitride film formed by a low pressure chemical vapor deposition (LPCVD) method. Also, from the result of SIMS analysis, it can be seen that a silicon nitride film formed by the atomic layer deposition method contains more hydrogen atoms than a silicon nitride film formed by the LPCVD method. Meanwhile, the wet etching rate of a silicon nitride film formed by the LPCVD method is smaller than the wet etching rate of a silicon nitride film formed by the atomic layer deposition method. Accordingly, it can be seen that when the amount of hydrogen atoms included in a silicon nitride film increases, the wet etching rate of the silicon nitride film increases (the film quality of the silicon nitride film deteriorates).

FIG. 10 is a graph illustrating an example of a relationship between an intensity of one peak caused by hydrogen atoms and a wet etching rate of a silicon nitride film in 0.5% hydrofluoric acid aqueous solution. The vertical axis represents a peak intensity caused by hydrogen atoms at a peak wavelength of 656.2 nm. The horizontal axis represents the kinds of plasma generating gases G. In FIG. 10, it can be seen that the peak intensity is scarcely changed between gas 4 which forms a silicon nitride film having a wet etching rate of 1.1 and gas 3 which forms a silicon nitride film having a wet etching rate of 0.49. Also, the peak intensity of gas 1 which forms a silicon nitride film having a wet etching rate of 0.53 is larger than the peak intensity of gas 3 which forms a silicon nitride film having a wet etching rate of 0.49. That is, there is no correlation between the peak intensity and the wet etching rate of a silicon nitride film as the correlation between the intensity ratio and the wet etching rate of a silicon nitride film as illustrated in FIG. 9. Accordingly, it is believed that it is difficult to predict the film quality of a silicon nitride film only based the peak intensity caused by hydrogen atoms at the peak wavelength of 656.2 nm.

The peak intensity caused by hydrogen atoms at a peak wavelength of 486.1 nm showed the same tendency as that in FIG. 10. Accordingly, it is believed that it is difficult to predict the film quality of a silicon nitride film only based on the peak intensity caused by hydrogen atoms at the peak wavelength of 486.1 nm Also, there is no correlation between the peak intensity caused by N₂ at a peak wavelength of 337.1 nm and the wet etching rate of a silicon nitride film as illustrated in FIG. 8 as the correlation between the intensity ratio and the wet etching rate of a silicon nitride film as illustrated in FIG. 9. Accordingly, it is believed that it is difficult to predict the film quality of a silicon nitride film only based on the peak intensity caused by N₂ at the peak wavelength of 337.1 nm.

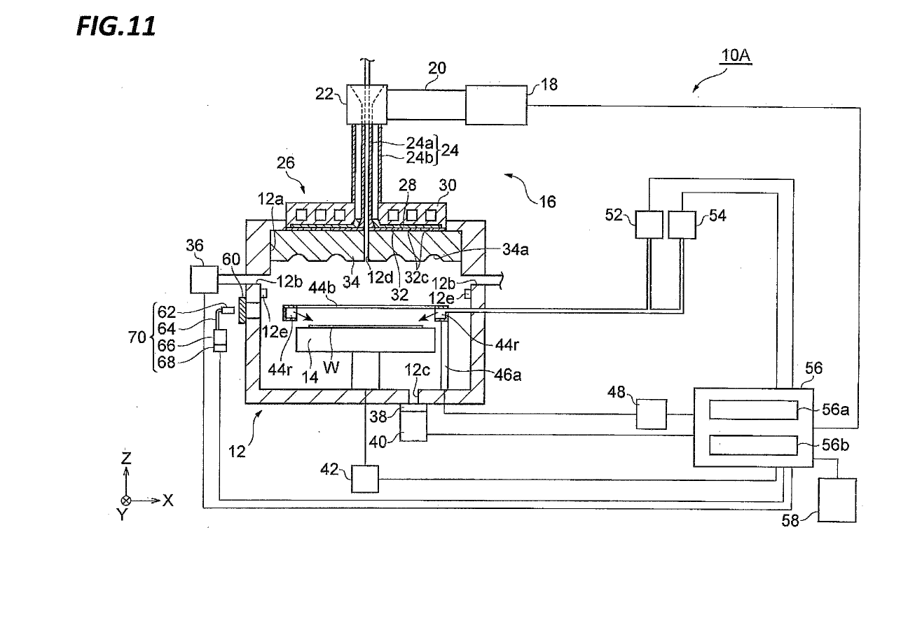

FIG. 11 is a cross-sectional view schematically illustrating a plasma processing apparatus according to an exemplary embodiment. The plasma processing apparatus 10A illustrated in FIG. 11 is provided with the same configuration as the plasma processing apparatus 10 except for the following features.

The plasma processing apparatus 10A is provided with a doughnut-shaped head unit 44b, instead of the head unit 44. The head unit 44b is supported by a support unit 46a. The head unit 44b may be configured to be rotated in the XY plane.

The head unit 44b has a ring unit 44r formed with gas supply holes that are provided to be oriented to the center of a substrate W. The gas supply holes are configured to supply an atomic layer deposition raw material gas (precursor) and a purge gas on the substrate W. The ring unit 44r is made of, for example, quartz. The raw material gas contains, for example, a silicon-containing compound. The purge gas contains an inert gas such as, for example, Ar gas or nitrogen gas. The ring unit 44r is disposed along the outer circumference of the substrate W. An atomic layer deposition raw material gas supply source 52 and a purge gas supply source 54 are connected to and communicated with the ring unit 44r. The raw material gas and the purge gas are supplied to the head unit 44b from the raw material gas supply source 52 and the purge gas supply source 54, respectively, and then supplied inwardly onto the substrate W from the ring unit 44r.

Concave portions 34a are formed on the bottom surface of a dielectric window 34 in the plasma processing apparatus 10A. Since a standing wave of microwave is suppressed, the microwave is efficiently transmitted through the dielectric window 34 and introduced into a chamber 12. As a result, uniform plasma P is generated. A plasma processing gas supply hole 12d is formed in the dielectric window 34. The gas supply hole 12d penetrates the center of the dielectric window 34 and a slot plate 32 to communicate with an inner waveguide 24a. A gas G supplied from a gas supply source 36 may be supplied into the processing chamber 12 from the gas supply hole 12d through the inside of the inner waveguide 24a. A nitriding gas such as, for example, NH₃ gas, N₂ gas, or Ar gas, a plasma generating gas, and a purge gas are supplied from the gas supply hole 12d.

A plurality of plasma processing gas supply holes 12b are formed along the annular region on the side wall of the processing chamber 12 in the plasma processing apparatus 10A. The gas supply holes 12b are uniformly and radially formed from the outside to the center of the processing chamber 12 to communicate with a ring-shaped gap formed within the inside of the side wall of the processing chamber 12. A plasma generating gas and a purge gas such as, for example, N₂ gas, or Ar gas, are supplied from the gas supply holes 12b. A nitriding gas such as, for example, NH₃ gas, may be supplied.

The plasma processing apparatus 10A is provided with an edge ring 12e that has an annular ring member formed with plasma processing gas supply holes. In the edge ring 12e, the gas supply holes 12b are uniformly formed toward the substrate W, and toward the center within the chamber 12. The edge ring 12e is made of, for example, quartz. The gas G supplied from the gas supply source 36 may be supplied into the processing chamber 12 from the edge ring 12e. A nitriding gas such as, for example, NH₃ gas, N₂ gas, or Ar gas, a plasma generating gas, and a purge gas are supplied from the gas supply hole 12e.

The gas species, the gas flow rates, the flow rate ratios and the gas flowing times of the gases G supplied from gas supply holes 12b, and 12d, and the edge ring 12e may be independently controlled.

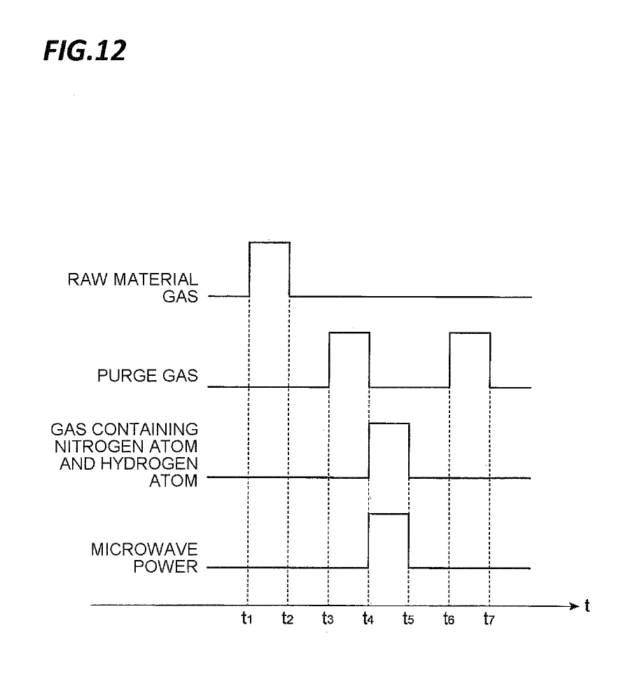

FIG. 12 is a timing chart schematically illustrating a plasma processing method according to an exemplary embodiment. The plasma processing method according to the present exemplary embodiment includes a step of performing a plasma processing on a layer adsorbed on a substrate W by using plasma P evaluated by the plasma evaluation method. Accordingly, a nitride film of a good film quality is formed on the substrate W.

The plasma processing method is performed by repeating the following steps 1 to 4 by using, for example, the plasma processing apparatus 10A. Accordingly, a nitride film with a thickness of, for example, 1 nm to 15 nm, is formed.

(Step 1) In the processing chamber 12, a raw material gas such as, for example, dichlorosilane, is adsorbed on the substrate W to generate a silicon-containing compound (timing t1 to t2). In an example, the raw material gas contains Ar (the flow rate from the gas supply holes 12b: 900 sccm), N₂ (the flow rate from the gas supply holes 12b: 900 sccm) and dichlorosilane (the flow rate from the ring unit 44r: 280 sccm).

(Step 2) As needed, the inside of the processing chamber 12 is evacuated (timing t2 to t3), and an excessively adsorbed raw material gas is removed by a purge gas (timing t3 to t4). In an example, the purge gas contains Ar (the flow rate from the gas supply holes 12b: 900 sccm, and the flow rate from the gas supply hole 12d and the edge ring 12e: 500 sccm, and the flow rate from the ring unit 44r: 500 sccm), N₂ (the flow rate from the gas supply holes 12b: 900 sccm) and ammonia (the flow rate from the gas supply hole 12d and the edge ring 12e: 400 sccm).

(Step 3) A layer made of the raw material gas (the silicon-containing compound) adsorbed on the substrate W is subjected to a plasma nitriding processing by using plasma P generated from a gas G such as, for example, ammonia (timing t4 to t5). The plasma P is generated by turning ON the power of microwave (e.g., 4000 W).

(Step 4) If needed, the inside of the processing chamber 12 is evacuated (timing t5 to t6), and a gas remaining within the processing chamber 12 is removed by a purge gas (timing t6 to t7). The purge gas in step 4 may be the same as the purge gas in step 2.

The above described steps 1 to 4 are set as one cycle to form a silicon nitride film with a required film thickness (e.g., 1 nm to 15 nm).

Before performing the above described steps 1 to 4, the substrate W may be subjected to a plasma nitriding processing in advance by using plasma P generated from a gas G that contains nitrogen atoms and hydrogen atoms.

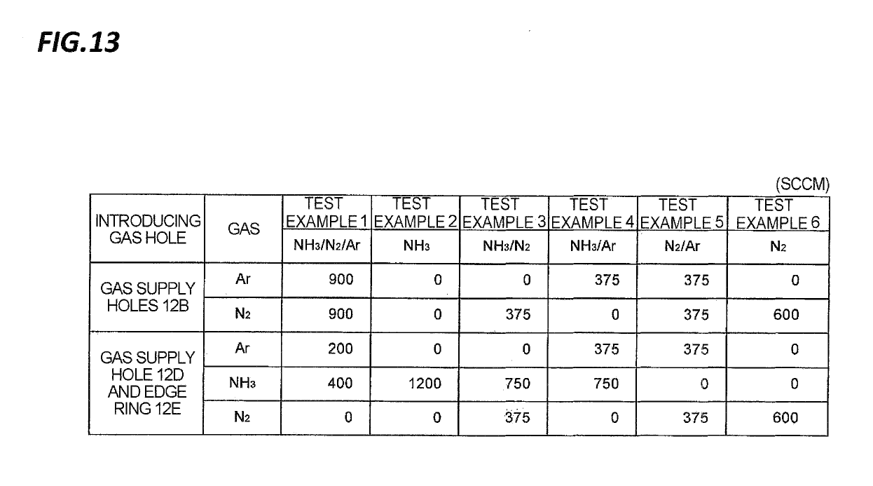

The silicon nitride films in test examples in FIGS. 9 and 10 were formed by the plasma processing apparatus 10A of FIG. 11. FIG. 13 is a table representing examples of gas flow rates when silicon nitride films are formed. FIG. 13 represents the flow rates of respective gases included in the gas G to be supplied from the gas supply holes 12b and 12d and the edge ring 12e in step 3 to be described later, in test examples 1 to 6. In the examples, the pressure within the processing chamber 12 is 5 Torr and the temperature is 400° C. during the plasma processing. In test examples 1 to 6, the flow rate of Ar from the ring unit 44r is, for example, 100 sccm. Experimental examples 1 to 4 correspond to gas flow rates when forming silicon nitride films in the test examples of FIGS. 9 and 10.

Although exemplary embodiments of the present disclosure have been described in detail above, the present disclosure is not limited to the exemplary embodiments.

### DESCRIPTION OF SYMBOLS

10: plasma processing apparatus
12: processing chamber
16: plasma generator
26: radial line slot antenna
36: gas supply source
56: control unit
70: light detector
G: a gas containing nitrogen atoms and hydrogen atoms
P: plasma.

1. A plasma evaluation method of evaluating plasma that forms a nitride film by an atomic layer deposition method, the plasma evaluation method comprising:
detecting light emission from the plasma generated from a gas that contains nitrogen atoms and hydrogen atoms; and
performing evaluation of the plasma by using a result of comparing an intensity ratio between a first peak caused by hydrogen atoms and a second peak different from the first peak and caused by hydrogen atoms in an intensity spectrum of the detected light emission with a reference value calculated in advance from a relationship between the intensity ratio and an indicator that indicates a film quality of the nitride film.

2. The plasma evaluation method of claim 1, wherein the first peak has a peak wavelength of 656.2 nm, and the second peak has a peak wavelength of 486.1 nm.

3. The plasma evaluation method of claim 1, further comprising, when the intensity ratio is less than the reference value, changing a condition of the plasma so that the intensity ratio becomes equal to or larger than the reference value after the evaluation of the plasma.

4. The plasma evaluation method of claim 3, wherein after the changing of the condition of the plasma, the method returns back to the detecting of the light emission from the plasma.

5. The plasma evaluation method of claim 1, wherein the plasma is generated by microwave.

6. The plasma evaluation method of claim 5, wherein the plasma is generated by a radial line slot antenna.

7. A plasma processing method comprising:
performing a plasma processing on a layer adsorbed on a substrate by using the plasma evaluated by the plasma evaluation method of claim 1.

8. A plasma processing apparatus that forms a nitride film by an atomic layer deposition method, the apparatus comprising:
a processing chamber;
a gas supply source configured to supply a gas that contains nitrogen atoms and hydrogen atoms into the processing chamber;
a plasma generator configured to generate plasma from the gas within the processing chamber;
a light detector configured to detect light emission from the plasma; and
a control unit that performs evaluation of the plasma by using a result of comparing an intensity ratio between a first peak caused by hydrogen atoms and a second peak different from the first peak and caused by the hydrogen atoms in an intensity spectrum of the detected light emission with a reference value calculated in advance from a relationship between the intensity ratio and an indicator that indicates a film quality of the nitride film.
